(19) United States
(12) Patent Application Publication
(10) Pub. No.: US 2026/0322389 A1
(43) Pub. Date: Oct. 15, 2026

(54) CURRENT STEERING DIGITAL-TO-ANALOG CONVERTER WITH REDUCED INTER-CELL INTERFERENCE

(71) Applicant: MEDIATEK INC., hSINCHU cITY (TW)

(72) Inventors: SUJITH KUMAR BILLA, Hsinchu City (TW); Sung-Han Wen, Hsinchu City (TW)

(73) Assignee: MEDIATEK INC., hSINCHU cITY (TW)

(21) Appl. No.: 19/722,958

(22) Filed: Jun. 28, 2026

Related U.S. Application Data
(63) Continuation of application No. 18/822,479, filed on Sep. 3, 2024, now Pat. No. 12,683,620.
(60) Provisional application No. 63/580,404, filed on Sep. 4, 2023.

(51) Int. Cl. H03M 1/08; H03M 1/74

(52) U.S. Cl. CPC H03M 1/0827; H03M 1/747

(57) ABSTRACT

A DAC cell circuit includes a plurality of DAC cells coupled in parallel, each DAC cell including: a first MOSFET coupled to a first switch and a second switch for receiving a first and second current, and a gate coupled to a first bias voltage; and a dead-band switch coupled between the gate of the first MOSFET and the bias node. The DAC cell circuit further includes: a voltage generating circuit coupled to the first current and the second current; and a reference voltage coupled to the source of the first MOSFET of each DAC cell. Inputs to the first switch and the second switch are binary, the dead-band switches are open during a data transition, and the dead-band switches are controlled by a periodic signal with respect to a frequency equal to an input data rate of the plurality of DAC cells.

### CROSS REFERENCE TO RELATED APPLICATION

This application is a continuation application of U.S. application Ser. No. 18/822,479, filed on Sep. 3, 2024, which claims the benefit of U.S. Provisional Application No. 63/580,404, filed on Sep. 4, 2023. The contents of these applications are incorporated herein by reference.

### BACKGROUND

The invention is directed to a current steering Digital-to-analog Converter (DAC), and more particularly, to a current steering DAC which has reduced inter-cell interference.

DAC is a data converter which receives a digital input and generates an analog output. DACs are commonly used in music players to generate an analog audio output from a digital data stream, as well as in televisions and mobile phones to generate an analog video output from digital video data. DACs used for video output are typically high frequency devices with low to medium resolution whereas DACs used primarily for audio output are typically low frequency devices with high resolution.

FIG. 1 illustrates a single DAC cell 100 comprising a first switch P₍ᵢ₎, a second switch N₍ᵢ₎, a capacitor, and a tail transistor/MOSFET Mn₍ᵢ₎. The capacitor and MOSFET are coupled to a bias line at a common bias node which receives a bias voltage V_{NBias}. Note that the switches in FIG. 1 are illustrated as simple switches but can be implemented by any structure such as MOSFETs. The capacitor represents the gate-to-drain capacitance. The bias voltage dictates the current of the DAC cell 100.

The input of the DAC cell 100 is a digital sequence which, when passed through the DAC cell, should be represented at its output as an analog equivalent of the input sequence. The inputs to the switches are binary (i.e. 0 or 1), and open and close such that when P₍ᵢ₎ receives a positive input or 1, N₍ᵢ₎ receives a negative input or 0 and vice versa. When the inputs to the switches change, the DAC cell 100 will undergo a transition. All DAC cells will have some non-ideal transient behavior such as a finite settling time and asymmetric rise and fall times, and non-ideal static behavior such as a transfer function deviating from a straight line.

FIG. 2A~2C show the DAC cell 100 undergoing an input data change from D₍ᵢ₎=+1→−1. In FIG. 2A, switch P₍ᵢ₎ is closed and switch N₍ᵢ₎ is open. In FIG. 2B, switch P₍ᵢ₎ opens. As switch N₍ᵢ₎ is still open, channel charge of the switch −Q will be stored on the capacitor. This will lead to voltage transitions on the drain and the bias nodes.

In FIG. 2C, the switch P₍ᵢ₎ is still open and switch N₍ᵢ₎ closes. The charge-Q deposited on the capacitor will be transmitted to the channel of the switch N₍ᵢ₎, and the voltage bias will return to normal.

When DAC cells are coupled together in a larger circuit, as illustrated in FIG. 3A~FIG. 3C, transitions on the bias node will be visible at the DAC output. Transitions on the bias node mean the output spectrum of the DAC will contain harmonics, which will present as distortion in the output signal. When the DAC is used in an audio circuit, this harmonic distortion will cause problems in the output signal. Second-order or ‘even’ harmonics are even-numbered multiples of the fundamental frequencies and create a rich, pleasing sound. Third-order or ‘odd’ harmonics are odd-numbered multiples of the fundamental frequencies, which give the signal an edgier, more aggressive sound.

In FIG. 3A, the DAC is at a steady state with all P switches closed and all N switches open. In FIG. 3B, the first three P switches are closed and the final P switch is open; similarly, the first three N switches are open and the final N switch is closed. To go from the state shown in FIG. 3A to the state shown in FIG. 3B therefore involves one transition, which will be seen on the bias node and at the output of the DAC.

In FIG. 3C, the first two P switches are closed and the last two P switches are open; similarly, the first two N switches are open and the last two N switches are closed. To go from the state shown in FIG. 3A to the state shown in FIG. 3C therefore involves two transitions, which will be seen on the bias node and at the output of the DAC.

The common mode error is represented by the following equation: Common mode error=2×|D[n]−D[n−1]|gₘΔVₑ.

The differential error is represented by the following equation:

Differential error=D[n]×|D[n]−D[n−1]|gₘΔVₑ

In the above, the term D[n] represents the fundamental harmonics of the signal. The term D[n]−D[n−1] is proportional to the input signal; therefore, if the input is reduced then this term will also be reduced. This term is a linear operation but its absolute value |D[n]−D[n−1]| will have even harmonics, such that when it is multiplied with the fundamental harmonic in D[n], odd order harmonics will be seen at the output of the DAC.

A common implementation of a DAC is a 17-level DAC consisting of eight tri-state DAC cells, as illustrated in FIG. 4, wherein each tri-state cell within the DAC operates in three operational states according to an input of +1, −1, or 0. During transitions, the gate-to-drain capacitor coupling of the tail transistors will cause even-order harmonics to be present on the bias nodes, which will mix with the fundamental harmonics at the input to the tri-state DAC, producing odd-order (third-order) harmonics at the output of the tri-state DAC. The even-order harmonics are proportional to the input amplitude. When the input amplitude is raised by a certain amount, the second-order harmonics will increase proportionally, thereby also increasing the third-order harmonics, which will limit the peak SDNR of the tri-state DAC.

### SUMMARY

It is therefore an objective of the present invention to provide a DAC cell which can reduce odd-order harmonics at the output. This is achieved by providing a dead band switch coupled to at least one transistor within a DAC cell, wherein the dead band switch is controlled by a periodic signal.

A DAC cell circuit according to an exemplary embodiment comprises a plurality of DAC cells coupled in parallel. Each DAC cell comprises: a first MOSFET having a drain coupled to a first switch for receiving a first current and coupled to a second switch for generating a second current, a source coupled to ground, and a gate coupled to a first bias voltage; a capacitor coupled between the gate and the drain of the first MOSFET; and a dead-band switch coupled between the gate of the first MOSFET and the bias node. The DAC cell circuit further comprises: a voltage generating circuit coupled to the first current and the second current for generating a differential output voltage; and a reference voltage coupled to the source of the first MOSFET of each DAC cell. Inputs to the first switch and the second switch are binary, the dead-band switches are open during a data transition, and the dead-band switches are controlled by a signal which is periodic with respect to a frequency which is equal to an input data rate of the plurality of DAC cells.

A complementary DAC cell circuit according to an exemplary embodiment comprises two DAC cell circuits coupled together in a mirrored architecture. Each DAC cell circuit comprises a plurality of DAC cells coupled in parallel. Each DAC cell comprises: a first MOSFET having a drain coupled to a first switch for receiving a first current and coupled to a second switch for generating a second current, a source coupled to ground, and a gate coupled to a first bias voltage; a capacitor coupled between the gate and the drain of the first MOSFET; and a dead-band switch coupled between the gate of the first MOSFET and the bias node. Each DAC cell circuit further comprises: a voltage generating circuit coupled to the first current and the second current for generating a differential output voltage; a reference voltage coupled to the source of the first MOSFET of each DAC cell; a common mode voltage; a plurality of switches coupled between the common mode voltage and the drain of the first MOSFET of each DAC cell; first and second differential common mode voltages; and differential dead-band switches coupled between the differential output voltage and the differential common mode voltages. The dead-band switches are open during a data transition, the dead-band switches are controlled by a signal which is periodic with respect to a frequency which is equal to an input data rate of the plurality of DAC cells.

In another exemplary embodiment, a DAC cell circuit comprises: a plurality of DAC cells coupled in parallel. Each DAC cell comprises: a first MOSFET having a drain coupled to a first switch for receiving a first current and coupled to a second switch for generating a second current, a source coupled to ground, and a gate coupled to a first bias voltage; a capacitor coupled between the gate and the drain of the first MOSFET; and a dead-band switch coupled between the gate of the first MOSFET and the bias node. The DAC cell circuit further comprises: a voltage generating circuit coupled to the first current and the second current for generating a differential output voltage; a reference voltage coupled to the source of the first MOSFET of each DAC cell; a common mode voltage; and a plurality of switches coupled between the common mode voltage and the drain of the first MOSFET of each DAC cell, each switch of the plurality of switches controlled by an input T₍ₖ₎, for k=0,1, . . . , L−1. The dead-band switches are open during a data transition, and the dead-band switches are controlled by a signal which is periodic with respect to a frequency which is equal to an input data rate of the plurality of DAC cells.

In another exemplary embodiment, a DAC cell circuit comprises: a plurality of DAC cells coupled in parallel. Each DAC cell comprises: a plurality of cascode MOSFETs, a top MOSFET of the plurality of cascode MOSFETs having a drain coupled to a first switch for receiving a first current and coupled to a second switch for generating a second current, a source coupled to ground, and a gate coupled to a bias voltage; a capacitor coupled between the gate and the drain of the top MOSFET; and a dead-band switch coupled between the gate of one of the plurality of cascode MOSFETs and the bias node. The DAC cell circuit further comprises: a voltage generating circuit coupled to the first current and the second current for generating a differential output voltage; a reference voltage coupled to the source of a bottom MOSFET of the plurality of cascode MOSFETs of each DAC cell; a common mode voltage; and a plurality of switches coupled between the common mode voltage and the drain of the top MOSFET of each DAC cell. The dead-band switches are open during a data transition, the dead-band switches are controlled by a signal which is periodic with respect to a frequency which is equal to an input data rate of the plurality of DAC cells.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a DAC cell according to the related art.

FIG. 2A is a diagram of a DAC cell undergoing a data transition according to the related art.

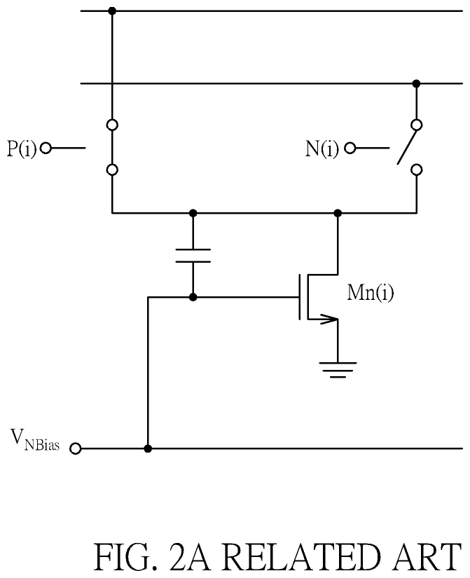

FIG. 2B is a diagram of a DAC cell undergoing a data transition according to the related art.

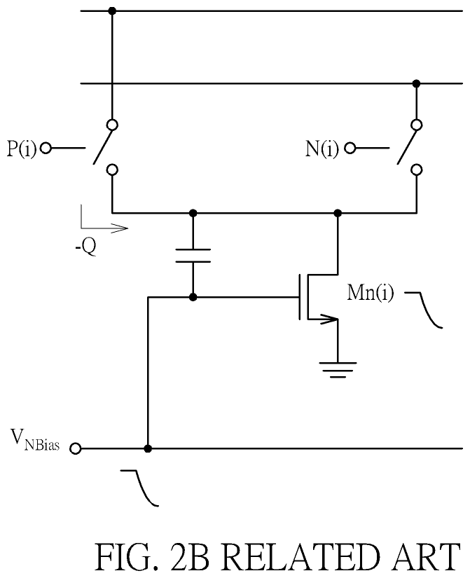

FIG. 2C is a diagram of a DAC cell undergoing a data transition according to the related art.

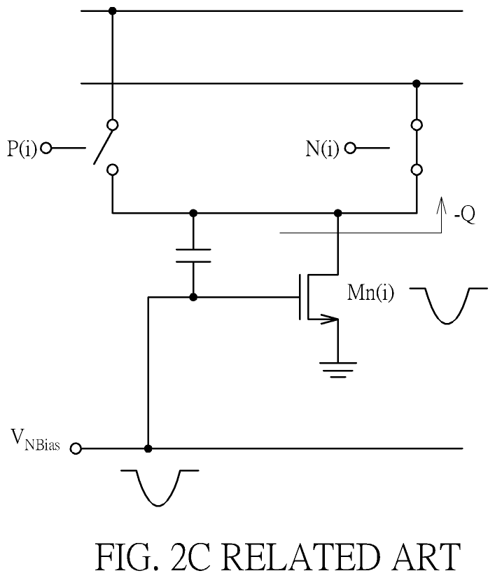

FIG. 3A is a diagram of a DAC cell circuit according to the related art.

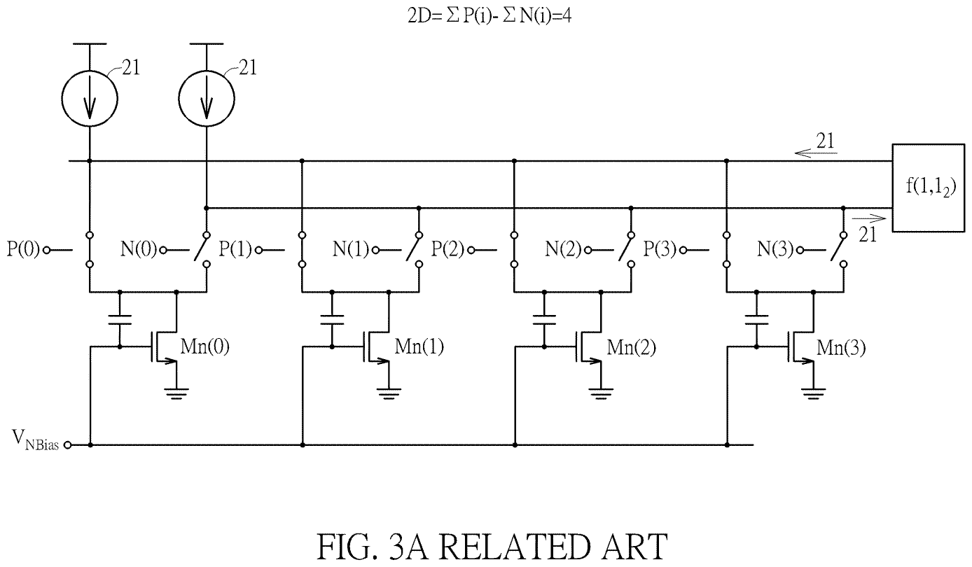

FIG. 3B is a diagram of a DAC cell circuit according to the related art.

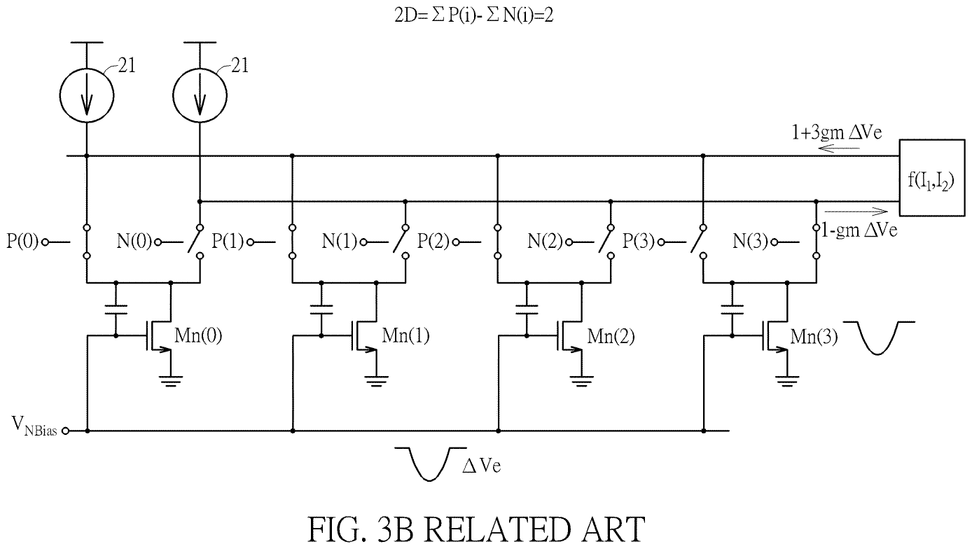

FIG. 3C is a diagram of a DAC cell circuit according to the related art.

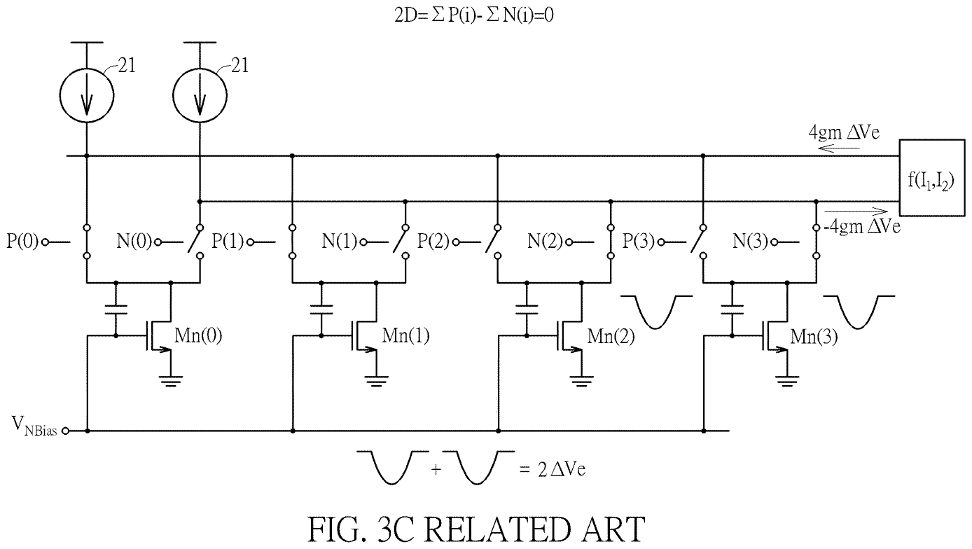

FIG. 4 is a diagram of a tri-state DAC cell circuit according to the related art.

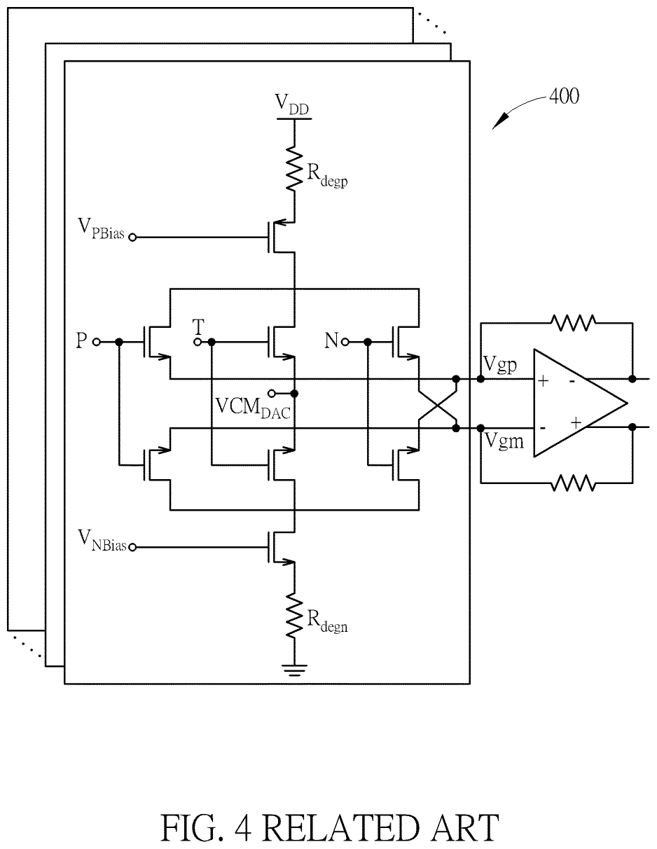

FIG. 5 is a diagram of a DAC cell according to an embodiment of the present invention.

FIG. 6A is a diagram of a DAC cell undergoing a data transition according to an embodiment of the present invention.

FIG. 6B is a diagram of a DAC cell undergoing a data transition according to an embodiment of the present invention.

FIG. 6C is a diagram of a DAC cell undergoing a data transition according to another embodiment of the present invention.

FIG. 6D is a diagram of a DAC cell undergoing a data transition according to another embodiment of the present invention.

FIG. 6E is a diagram of a DAC cell undergoing a data transition according to another embodiment of the present invention.

FIG. 7 is a diagram of a tri-state DAC cell according to an embodiment of the present invention.

FIG. 8 is a diagram of a DAC cell circuit according to an exemplary embodiment of the present invention.

FIG. 9 is a diagram of a DAC cell circuit according to an exemplary embodiment of the present invention.

FIG. 10 is a diagram of a DAC cell circuit according to an exemplary embodiment of the present invention.

FIG. 11 is a diagram of a DAC cell circuit according to an exemplary embodiment of the present invention.

FIG. 12 is a diagram of a DAC cell circuit according to an exemplary embodiment of the present invention.

FIG. 13 is a diagram of a DAC cell circuit according to an exemplary embodiment of the present invention.

FIG. 14 is a diagram of a DAC cell circuit according to an exemplary embodiment of the present invention.

FIG. 15 is a diagram of a DAC cell circuit according to an exemplary embodiment of the present invention.

### DETAILED DESCRIPTION

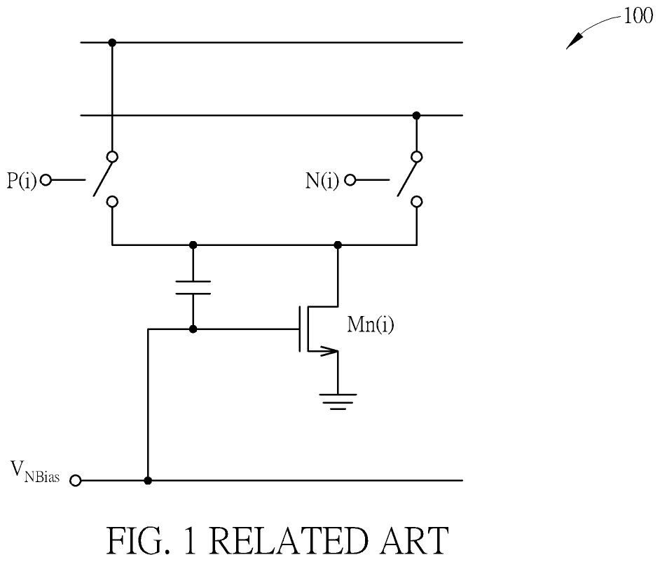

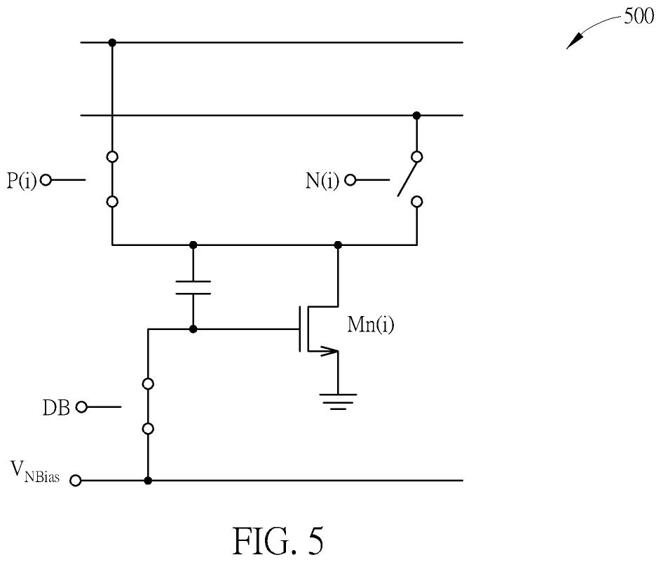

Refer to FIG. 5, which is a schematic diagram of a DAC cell 500 according to an exemplary embodiment of the present invention. As in the DAC cell 100 illustrated in FIG. 1, the DAC cell 500 comprises a first switch P₍ᵢ₎, a second switch N₍ᵢ₎, a capacitor, and a transistor/MOSFET Mn₍ᵢ₎, wherein the capacitor and MOSFET are coupled to a bias line at a common bias node which receives a bias voltage V_{NBias}. Different from the DAC cell 100, however, the DAC cell 500 further comprises a dead band switch (DB) which is coupled between the common bias node, the capacitor and the gate of the MOSFET. The dead band switch can be controlled by a periodic signal, and can work to isolate the MOSFET from the bias node during data transitions. This will be illustrated in the following.

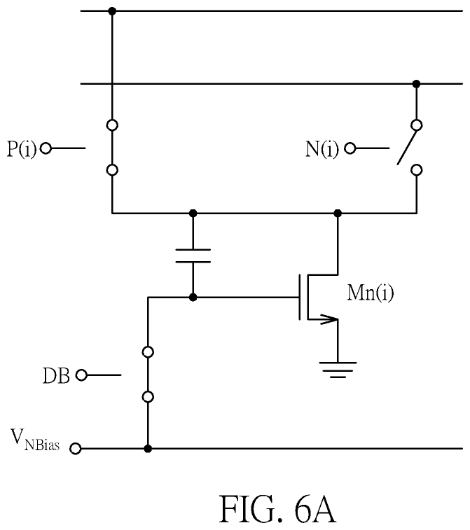

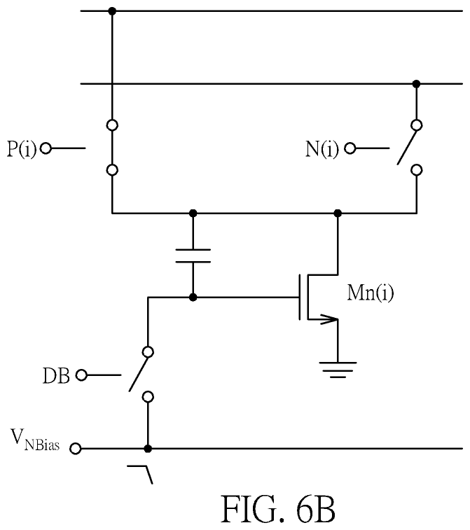

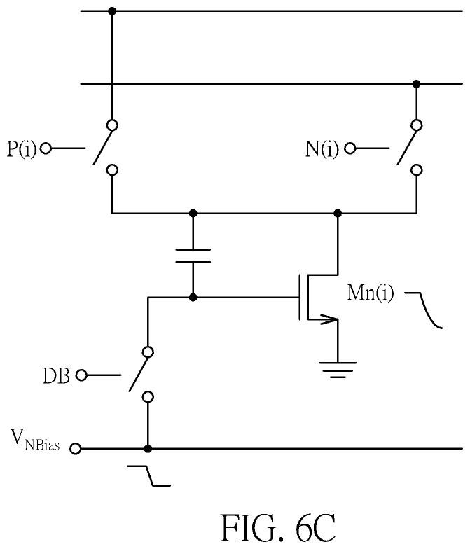

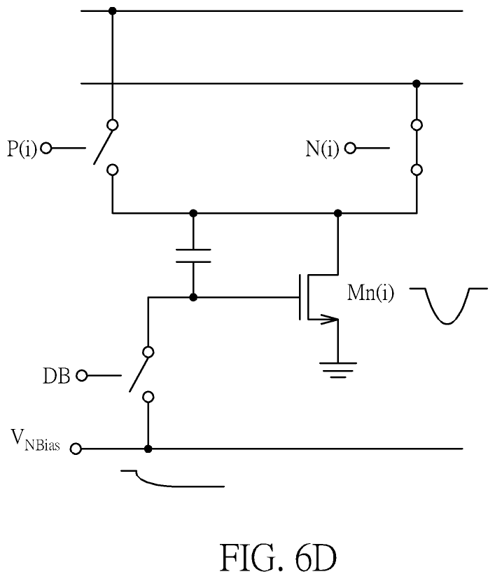

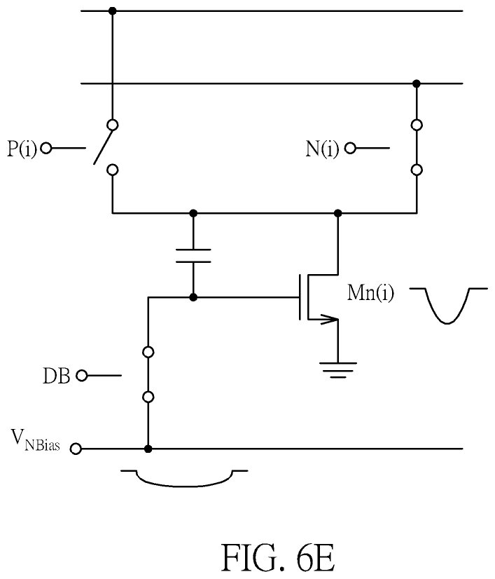

Refer to FIG. 6A~6E, which illustrate the DAC cell 500 undergoing a data transition from +1 to −1, wherein switch P₍ᵢ₎ goes from state 1 to 0 (i.e. closed to open), and switch N₍ᵢ₎ goes from state 0 to 1 (i.e. open to closed). As shown in FIG. 6A, switch P₍ᵢ₎ is closed, switch N₍ᵢ₎ is open, and the DB switch is closed. In FIG. 6B, the DB switch is open before any data transition to isolate any transitions occurring on the bias node. The effect of the DB switch opening will appear as a slight transition on the bias node. In FIG. 6C, switch P₍ᵢ₎ will open, while switch N₍ᵢ₎ and the DB switch also remain open. The transition because of the charge transfer to the capacitor will appear at the output of the MOSFET but this transition will not appear on the bias node.

In FIG. 6D, switch P₍ᵢ₎ and the DB switch remain open.

Switch N₍ᵢ₎ is closed so that the capacitor will be discharged. At this point, the transition on the output node will go back to the original level. In FIG. 6E, the DB switch will close again. At this point, only a small transition will occur on the bias node, such that the amplitude of any odd-order harmonics at the output of the DAC cell 500 will be minimized. The time between closing the switch N₍ᵢ₎ and closing the DB switch will depend on the size of the capacitor.

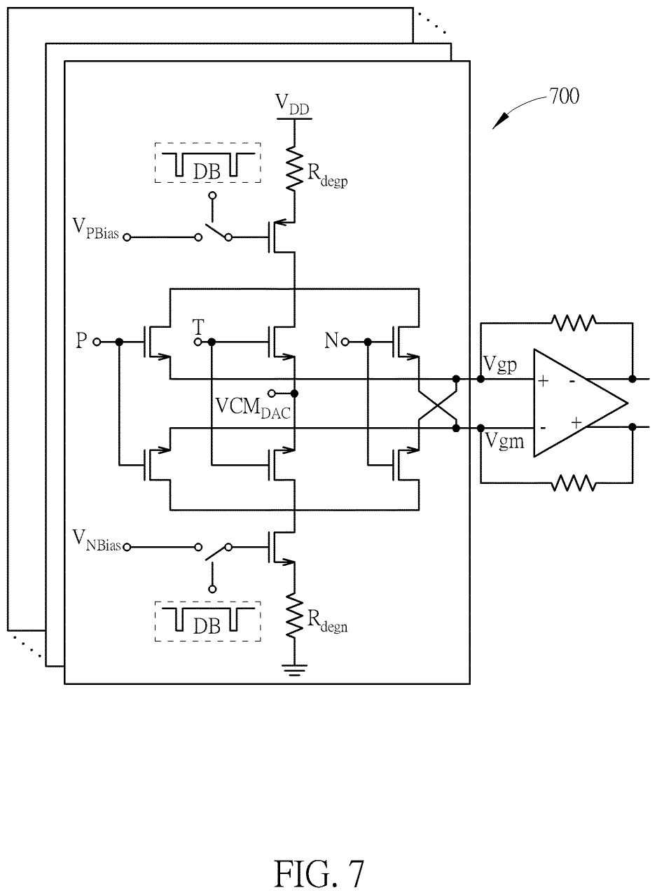

FIG. 7 illustrates a 17-level tri-state DAC applying the dead band switch architecture illustrated in FIG. 5. As shown in the diagram, there is a DB switch on the bias node in each of the DAC cells, and the DB switches are operated according to a periodic signal which has a frequency equal to the input data rate, wherein the DB switch is always open during a data transition. The isolation of the bias node via the DB switch means that the bias nodes exhibit reduced data-dependent transitions, meaning that there will be reduced even-order harmonics on the bias nodes. This means that the output of the DAC will exhibit reduced odd-order harmonics.

The proposed DAC cell structure incorporating a DB switch can be applied to a number of different circuit architectures, which will be detailed in the following.

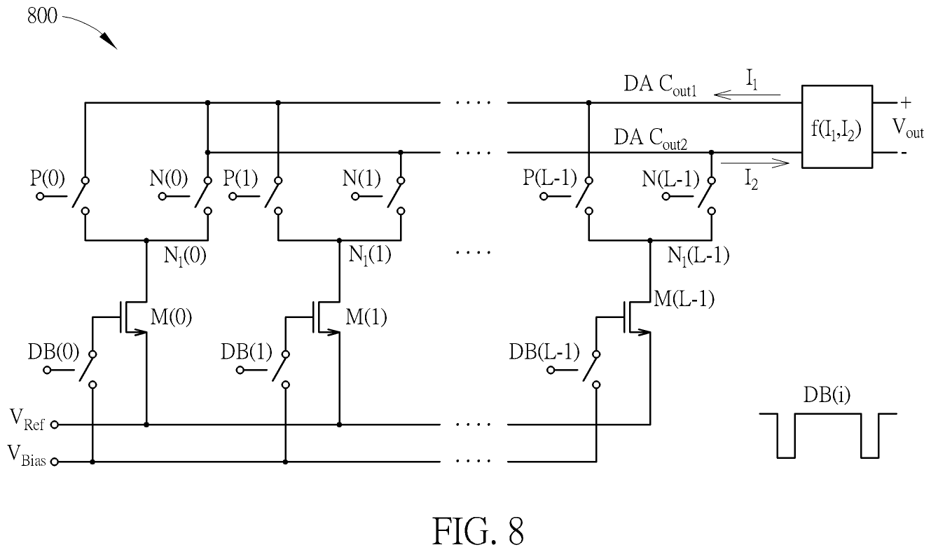

Refer to FIG. 8, which illustrates a plurality of DAC cells coupled in parallel, wherein each DAC cell comprises a DB switch coupled between the bias node and the gate of the MOSFET. Note that the capacitors in each DAC cell are not illustrated for simplicity, and that, as long as the DB switch structure controlled by a periodic signal is maintained, one skilled in the art may implement each DAC cell with a different architecture.

The differential output of the DAC cells is input to a processing circuit which receives the generated currents I₁ and I₂ and generates a differential Vₒᵤₜ signal. The DB switches are coupled to the bias node V_{Bias} and the sources of the MOSFETs of each DAC cell are coupled to a reference voltage V_{Ref}.

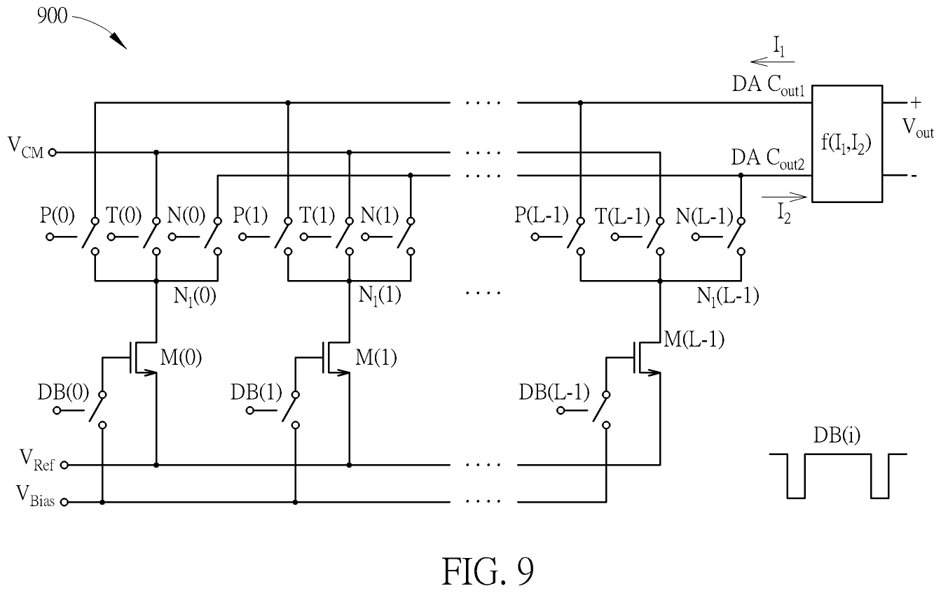

FIG. 9 illustrates a DAC circuit according to another embodiment. In this embodiment, each DAC cell further comprises a third switch T₍ₖ₎ coupled between the drain of the MOSFETs of each DAC cell and a common mode voltage V_{CM}, such that the DAC cell circuit in FIG. 9 is a tri-state circuit. The third switches are controlled by inputs T₍ₖ₎, for k=0,1, . . . , L−1.

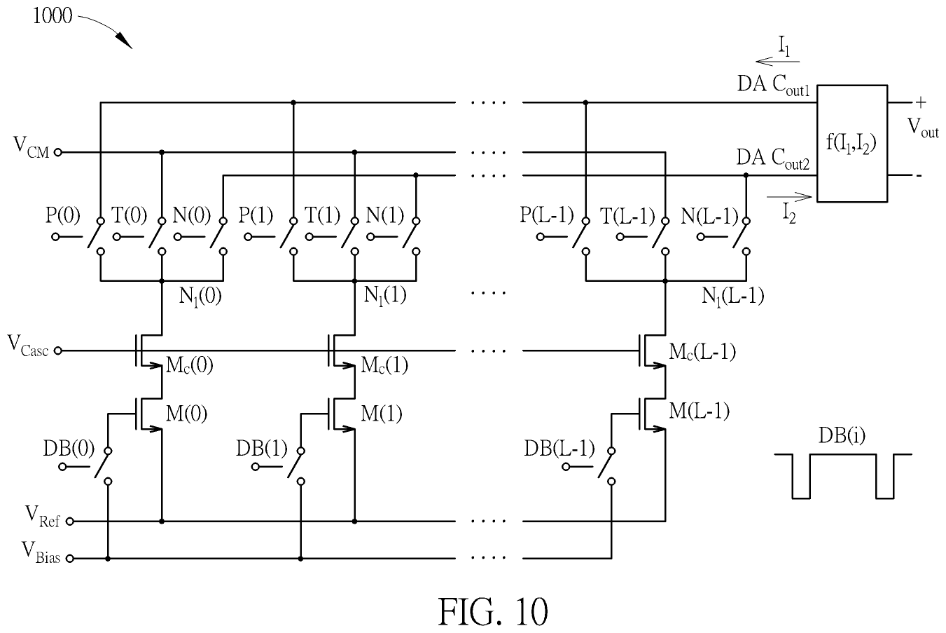

FIG. 10 illustrates a tri-state DAC circuit according to another embodiment. In this diagram, each DAC cell comprises two MOSFETs coupled in cascode, as well as a cascode voltage V_{Casc} coupled to the gates of the first cascode MOSFET of each DAC cell. In this embodiment, the DB switches are respectively coupled between the gates of the second cascode MOSFETs of each DAC cell and the bias voltage.

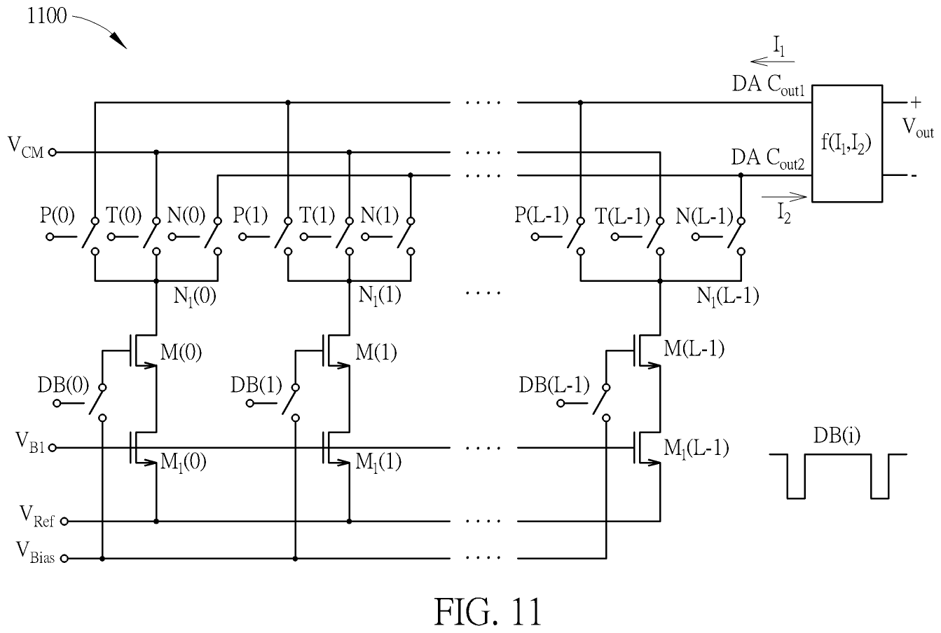

FIG. 11 also illustrates a DAC circuit comprising cascode

MOSFETs according to another embodiment of the present invention. In this embodiment, the DB switches are coupled between the gates of the first cascode MOSFET of each DAC cell and the bias voltage, and the circuit comprises a second bias voltage V_{B1} which is coupled to the gates of the second cascode MOSFET of each DAC cell. This embodiment isolates a different cascode transistor.

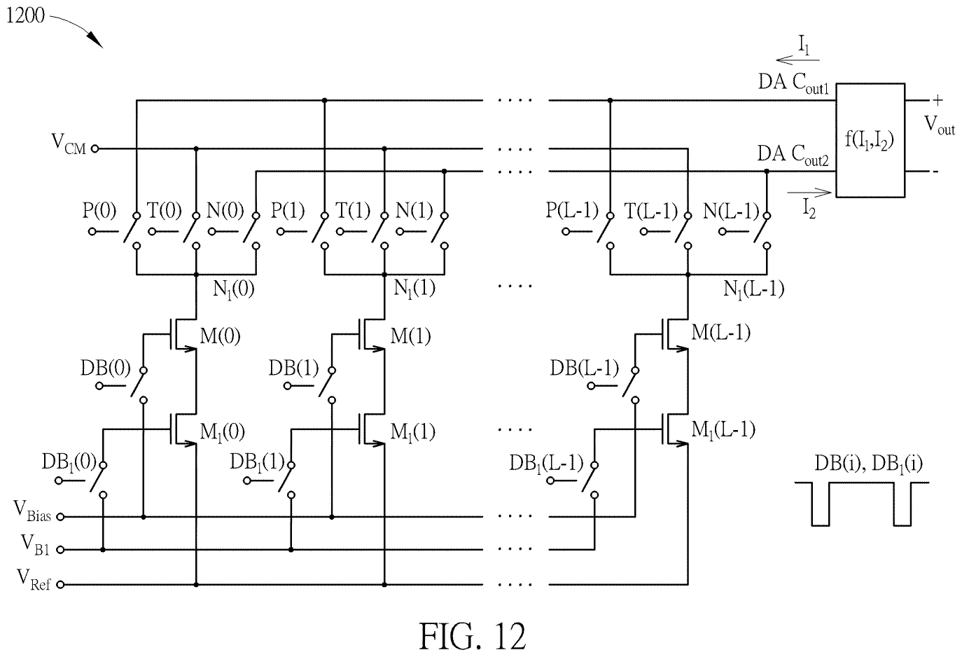

FIG. 12 illustrates another embodiment of a DAC circuit comprising cascode MOSFETs. In this embodiment, both cascode MOSFETs have a DB switch coupled to their respective gates, wherein the DB switches coupled to the second cascode MOSFETs are further coupled to a second bias voltage V_{B1}. The extra DB switch prevents transitions on the gates of both transistors.

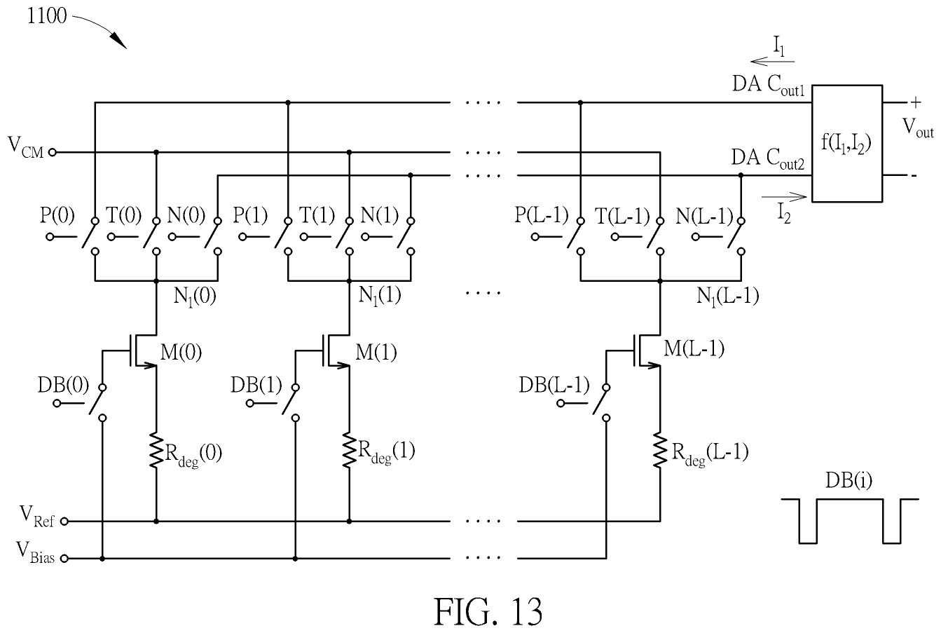

FIG. 13 illustrates a DAC circuit according to yet another embodiment of the present invention. This embodiment is a similar circuit to that illustrated in FIG. 9 but each DAC cell further comprises a resistor coupled between the source of each MOSFET and the reference voltage V_{Ref}.

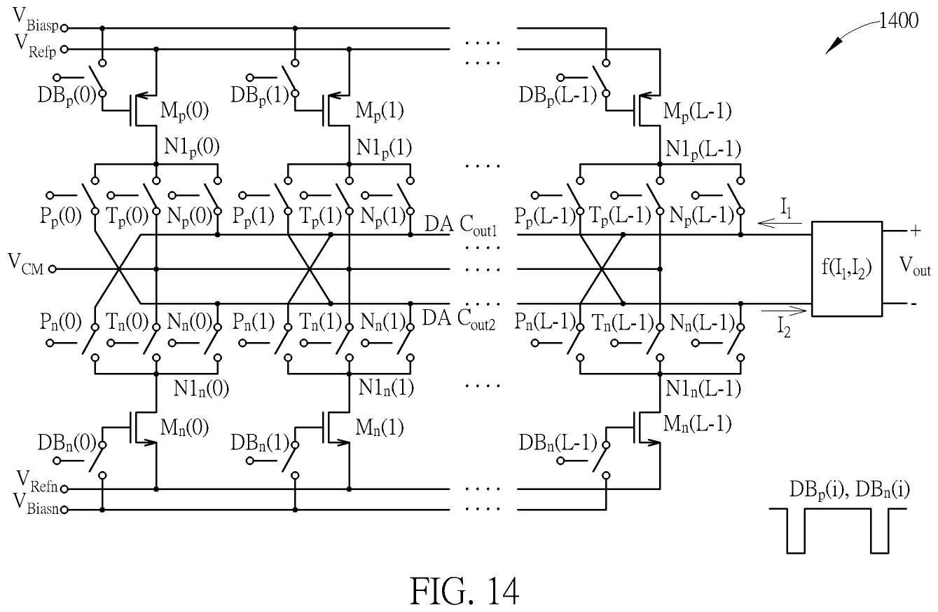

FIG. 14 illustrates a DAC circuit which is a complementary

DAC circuit comprising a mirrored DAC circuit of the circuit illustrated in FIG. 9.

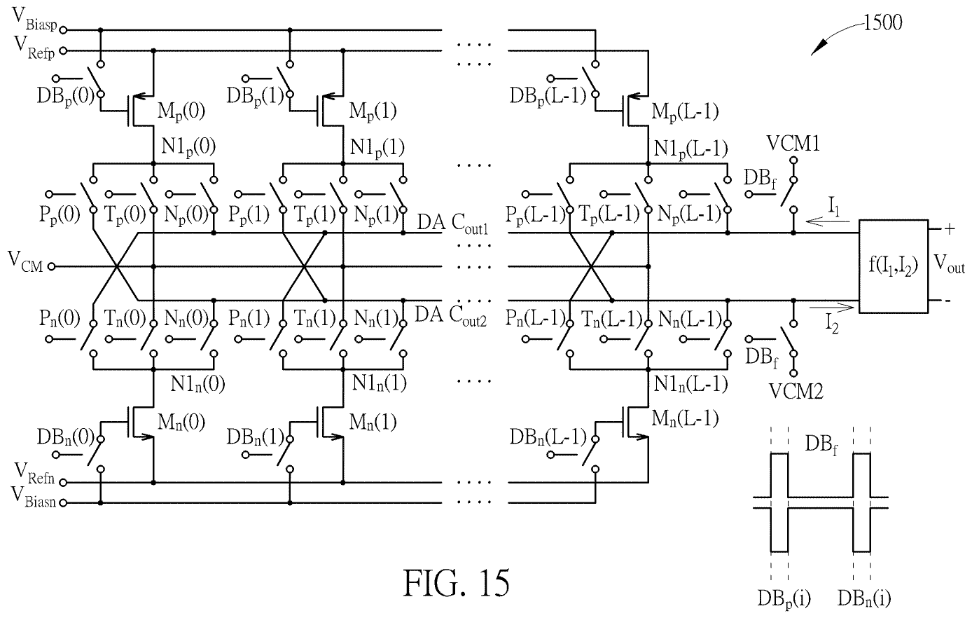

FIG. 15 is a modification of the DAC circuit illustrated in FIG. 14 and further comprises DB switches coupled between the processing circuit and differential common mode voltages V_{CM1}, V_{CM2}. In this embodiment, the DB periodic signals will be differential, wherein a first signal is the inverse of the second signal. These extra dead-band switches are used when coupling from inputs of the processing circuit (differential voltage generation circuit) to gates of the tail transistors is significant.

In all the circuits illustrated above, the transistors in each DAC cell may be implemented by NMOS, PMOS, NPN or PNP transistors. Note that cascode architecture in the above circuits is illustrated as comprising two cascode transistors, but any number of transistors may be coupled in cascode, wherein the number may be determined according to specific requirements. As long as a tail transistor of the cascode transistors is coupled to a common node reference voltage and at least one transistor of the cascode transistors has its gate coupled to a dead-band switch, different cascode architectures of a DAC cell will fall within the scope of the present invention. Also, note that the switches T₍ᵢ₎ are optional, wherein the presence of the switches makes the DAC cells tri-state and their absence makes them binary.

By providing dead band switches coupled to gates of transistors within a DAC cell, the bias node of a DAC cell can be isolated during data transitions. Further, inter-cell interference between DAC cells within a DAC cell circuit can be reduced. Extra dead-band switches coupled between bias nodes and the DAC outputs can further reduce coupling. The proposed DAC cell structure and DAC cell circuits of the present invention can thereby reduce odd-order harmonics present at an output of a DAC cell.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A DAC cell circuit comprising:
a plurality of DAC cells coupled in parallel, each DAC cell comprising:
a first MOSFET having a drain coupled to a first switch for receiving a first current and coupled to a second switch for generating a second current, a source coupled to ground, and a gate coupled to a first bias voltage;
a capacitor coupled between the gate and the drain of the first MOSFET; and
a dead-band switch coupled between the gate of the first MOSFET and the bias node;
a voltage generating circuit coupled to the first current and the second current for generating a differential output voltage; and
a reference voltage coupled to the source of the first MOSFET of each DAC cell;
wherein inputs to the first switch and the second switch are binary, the dead-band switches are open during a data transition, and the dead-band switches are controlled by a signal which is periodic with respect to a frequency which is equal to an input data rate of the plurality of DAC cells.

2. The DAC cell circuit of claim 1, wherein each DAC cell comprises a second MOSFET coupled in cascode above the first MOSFET, and the DAC cell circuit further comprises a cascode voltage coupled to the gate of the second cascode MOSFET of each DAC cell.

3. The DAC cell circuit of claim 2, wherein each DAC cell comprises a second MOSFET coupled in cascode below the first MOSFET, and the DAC cell circuit further comprises a second bias voltage coupled to a gate of the second cascode MOSFET of each DAC cell.

4. The DAC cell circuit of claim 3, wherein each DAC cell further comprises a second dead-band switch coupled between the second bias voltage and the gate of the second MOSFET.

5. The DAC cell circuit of claim 1, wherein each DAC cell comprises a resistor coupled between the source of the first MOSFET and the reference voltage.

6. A complementary DAC cell circuit comprising two DAC cell circuits of claim 1, coupled together in a mirrored architecture.

7. The DAC cell circuit of claim 1, wherein the MOSFET is a PMOS.

8. The DAC cell circuit of claim 1, wherein the transistor is an NMOS.

9. The DAC cell circuit of claim 1, wherein the MOSFET is an NPN transistor.

10. The DAC cell circuit of claim 1, wherein the MOSFET is a PNP transistor.

11. A complementary DAC cell circuit comprising two DAC cell circuits coupled together in a mirrored architecture, each DAC cell circuit comprising:
a plurality of DAC cells coupled in parallel, each DAC cell comprising:
a first MOSFET having a drain coupled to a first switch for receiving a first current and coupled to a second switch for generating a second current, a source coupled to ground, and a gate coupled to a first bias voltage;
a capacitor coupled between the gate and the drain of the first MOSFET; and
a dead-band switch coupled between the gate of the first MOSFET and the bias node;
a voltage generating circuit coupled to the first current and the second current for generating a differential output voltage;
a reference voltage coupled to the source of the first MOSFET of each DAC cell;
a common mode voltage;
a plurality of switches coupled between the common mode voltage and the drain of the first MOSFET of each DAC cell;
first and second differential common mode voltages; and
differential dead-band switches coupled between the differential output voltage and the differential common mode voltages;
wherein the dead-band switches are open during a data transition, the dead-band switches are controlled by a signal which is periodic with respect to a frequency which is equal to an input data rate of the plurality of DAC cells.

12. A DAC cell circuit comprising:
a plurality of DAC cells coupled in parallel, each DAC cell comprising:
a first MOSFET having a drain coupled to a first switch for receiving a first current and coupled to a second switch for generating a second current, a source coupled to ground, and a gate coupled to a first bias voltage;
a capacitor coupled between the gate and the drain of the first MOSFET; and
a dead-band switch coupled between the gate of the first MOSFET and the bias node;
a voltage generating circuit coupled to the first current and the second current for generating a differential output voltage;
a reference voltage coupled to the source of the first MOSFET of each DAC cell;
a common mode voltage; and
a plurality of switches coupled between the common mode voltage and the drain of the first MOSFET of each DAC cell, each switch of the plurality of switches controlled by an input T₍ₖ₎, for k=0,1, . . . , L−1;
wherein the dead-band switches are open during a data transition, and the dead-band switches are controlled by a signal which is periodic with respect to a frequency which is equal to an input data rate of the plurality of DAC cells.

13. A DAC cell circuit comprising:
a plurality of DAC cells coupled in parallel, each DAC cell comprising:
a plurality of cascode MOSFETs, a top MOSFET of the plurality of cascode MOSFETs having a drain coupled to a first switch for receiving a first current and coupled to a second switch for generating a second current, a source coupled to ground, and a gate coupled to a bias voltage;
a capacitor coupled between the gate and the drain of the top MOSFET; and
a dead-band switch coupled between the gate of one of the plurality of cascode MOSFETs and the bias node;
a voltage generating circuit coupled to the first current and the second current for generating a differential output voltage;
a reference voltage coupled to the source of a bottom MOSFET of the plurality of cascode MOSFETs of each DAC cell;
a common mode voltage; and
a plurality of switches coupled between the common mode voltage and the drain of the top MOSFET of each DAC cell;
wherein the dead-band switches are open during a data transition, the dead-band switches are controlled by a signal which is periodic with respect to a frequency which is equal to an input data rate of the plurality of DAC cells.

14. The DAC cell circuit of claim 13, further comprising a second bias voltage coupled to a gate of another cascode MOSFET of each DAC cell.

15. The DAC cell circuit of claim 14, wherein each DAC cell further comprises a second dead-band switch coupled between the second bias voltage and the gate of the other MOSFET.
